(19) United States
(12) Patent Application Publication
(10) Pub. No.: US 2025/0301883 A1
(43) Pub. Date: Sep. 25, 2025

(54) DISPLAY PANEL, MANUFACTURING METHOD FOR DISPLAY PANEL, AND ELECTRONIC DEVICE

(71) Applicants: Hefei Visionox Technology Co., Ltd., Hefei (CN); Visionox Technology Inc., Suzhou (CN)

(72) Inventors: Liusong NI, Hefei (CN); Yiming XIAO, Hefei (CN); Zhenhai YUE, Hefei (CN); Bowen YANG, Hefei (CN); Murong XUE, Hefei (CN); Chen XU, Hefei (CN); Tianwei ZHAI, Hefei (CN); Xiujian ZHU, Hefei (CN)

(73) Assignees: Hefei Visionox Technology Co., Ltd., Hefei (CN); Visionox Technology Inc., Suzhou (CN)

(21) Appl. No.: 18/779,681

(22) Filed: Jul. 22, 2024

(30) Foreign Application Priority Data
Mar. 21, 2024 (CN) 202410337713.0

(51) Int. Cl. H10K 59/80; H10K 59/12; H10K 59/122

(52) U.S. Cl. CPC H10K 59/873; H10K 59/1201; H10K 59/122

(57) ABSTRACT

A display panel, a manufacturing method for a display panel, and an electronic device. The display panel includes an array base plate, an isolation structure, a light-emitting device, a first encapsulation layer, and a second encapsulation layer. The isolation structure is located at one side of the array base plate, the isolation structure encloses and forms an isolation opening. At least a part of the light-emitting device is located in the isolation opening. The first encapsulation layer is located at a side of the light-emitting device away from the array base plate, the first encapsulation layer includes an encapsulation unit, a gap is provided between the encapsulation unit located at the side of the isolation structure away from the array base plate and the side of the isolation structure away from the array base plate.

### CROSS REFERENCE TO RELATED APPLICATION

The present application claims priority to Chinese Patent Application No. 202410337713.0 filed on Mar. 21, 2024, and titled “DISPLAY PANEL, MANUFACTURING METHOD FOR DISPLAY PANEL, AND ELECTRONIC DEVICE”, which is incorporated herein by reference in its entirety.

### TECHNICAL FIELD

The present application relates to the field of display technology, and particularly to a display panel, a manufacturing method for the display panel, and an electronic device.

### BACKGROUND

Planar display apparatus based on Organic Light Emitting Diode (OLED) and Light Emitting Diode (LED) are widely used in cell phones, TVs, notebook computers, desktop computers and other consumer electronic products due to their high image quality, power saving, thin body and wide range of applications, and have become the mainstream of the display panel.

However, some problems still need to be urgently solved for the display panel.

### SUMMARY

In order to overcome the technical problems mentioned in the above background, embodiments of the present application provide a display panel, including:
an array base plate;
an isolation structure located at one side of the array base plate, in which the isolation structure encloses and forms an isolation opening;
a light-emitting device at least partially located in the isolation opening;
a first encapsulation layer located at a side of the light-emitting device away from the array base plate, in which the first encapsulation layer includes an encapsulation unit, the encapsulation unit extends from a side surface of the isolation structure to a side of the isolation structure away from the array base plate, the side surface of the isolation structure is a surface of the isolation structure facing the isolation opening, and a gap is provided between the encapsulation unit located at the side of the isolation structure away from the array base plate and the side of the isolation structure away from the array base plate; and
a second encapsulation layer located at a side of the first encapsulation layer away from the array base plate, in which at least a part of the second encapsulation layer extends into the gap.

In some possible implementations, the present application further provides another display panel, including:
an array base plate;
an isolation structure located at one side of the array base plate, in which the isolation structure encloses and forms an isolation opening;
a light-emitting device at least partially located in the isolation opening; and
a first encapsulation layer located at a side of the light-emitting device away from the array base plate, in which the first encapsulation layer includes an encapsulation unit, the encapsulation unit extends from a side surface of the isolation structure to a side of the isolation structure away from the array base plate, the side surface of the isolation structure is a surface of the isolation structure facing the isolation opening, a gap is provided between the encapsulation unit located at the side of the isolation structure away from the array base plate and the side of the isolation structure away from the array base plate, and heights of gaps corresponding to light-emitting devices of different colors are not equal.

In some possible implementations, the present application further provides a manufacturing method for a display panel, including:
providing an array base plate;
forming an isolation structure at one side of the array base plate, in which the isolation structure encloses and forms an isolation opening;
forming at least a part of a light-emitting device in the isolation opening;
forming a first encapsulation layer at a side of the light-emitting device away from the array base plate, in which the first encapsulation layer includes an encapsulation unit, the encapsulation unit extends from a side surface of the isolation structure to a side of the isolation structure away from the array base plate, the side surface of the isolation structure is a surface of the isolation structure facing the isolation opening, and a gap is provided between a part of the encapsulation unit located at the side of the isolation structure away from the array base plate and the side of the isolation structure away from the array base plate; and
forming a second encapsulation layer at a side of the first encapsulation layer away from the array base plate, in which at least a part of the second encapsulation layer extends into the gap.

In some possible implementations, the present application further provides an electronic device, including the display panel in the present application, or including the display panel manufactured by the manufacturing method for the display panel in the present application.

In comparison with the prior art, the present application has the following beneficial effects:

In the display panel, the manufacturing method for the display panel, and the electronic device according to the present application, the second encapsulation layer can provide support for the overhanging encapsulation unit by extending at least a part of the second encapsulation layer into the gap, which can improve the stability of the encapsulation unit located at the side of the isolation structure away from the array base plate, so that the encapsulation unit is less likely to break, and thus the stability of the display panel can be improved.

### BRIEF DESCRIPTION OF THE DRAWINGS

FIG. 1 shows a schematic cross-sectional view of a display panel in the related art;

FIG. 2 shows a schematic cross-sectional view of a display panel according to an embodiment of the present application;

FIG. 3 shows a schematic cross-sectional view of a display panel including a third encapsulation layer according to an embodiment of the present application;

FIG. 4 shows a schematic cross-sectional view of an insulation structure including a three-layer structure according to an embodiment of the present application;

FIG. 5 shows a schematic flow diagram of a manufacturing method for a display panel according to an embodiment of the present application;

FIG. 6 shows a schematic cross-sectional view of forming a first electrode layer at one side of an array base plate according to an embodiment of the present application;

FIG. 7 shows a schematic cross-sectional view of forming a pixel definition material layer at a side of a first electrode layer away from an array base plate according to an embodiment of the present application;

FIG. 8 shows a schematic cross-sectional view of forming an isolation structure material layer located at a side of a pixel definition material layer away from an array base plate according to an embodiment of the present application;

FIG. 9 shows a schematic cross-sectional view of an insulation structure material layer after a dry etching treatment according to an embodiment of the present application;

FIG. 10 shows a schematic cross-sectional view of an isolation structure material layer after patterning according to an embodiment of the present application;

FIG. 11 shows a schematic cross-sectional view of a pixel definition material layer after patterning according to an embodiment of the present application;

FIG. 12 shows a schematic cross-sectional view of forming a light-emitting functional layer for a light-emitting device of a first color at a side of an isolation structure away from an array base plate according to an embodiment of the present application;

FIG. 13 shows a schematic cross-sectional view of forming a second electrode layer at a side of a light-emitting functional layer for a light-emitting device of a first color away from an array base plate according to an embodiment of the present application;

FIG. 14 shows a first schematic cross-sectional view of forming a first encapsulation layer at a side of a second electrode layer away from an array base plate according to an embodiment of the present application;

FIG. 15 shows a schematic cross-sectional view of forming a first etching protection layer at an isolation opening corresponding to a light-emitting device of a first color according to an embodiment of the present application;

FIG. 16 shows a schematic cross-sectional view of removing a first encapsulation layer, a light-emitting functional layer, and a second electrode layer that are not covered by a first etching protection layer and removing a first etching protection layer according to an embodiment of the present application;

FIG. 17 shows a schematic cross-sectional view of forming a light-emitting functional layer for a light-emitting device of a second color at a side of an isolation structure away from an array base plate according to an embodiment of the present application;

FIG. 18 shows a schematic cross-sectional view of forming a second electrode layer at a side of a light-emitting functional layer for a light-emitting device of a second color away from an array base plate according to an embodiment of the present application;

FIG. 19 shows a second schematic cross-sectional view of forming a first encapsulation layer at a side of a second electrode layer away from an array base plate according to an embodiment of the present application;

FIG. 20 shows a schematic cross-sectional view of forming a second etching protection layer at an isolation opening corresponding to a light-emitting device of a second color according to an embodiment of the present application;

FIG. 21 shows a schematic cross-sectional view of removing a first encapsulation layer, a light-emitting functional layer, and a second electrode layer for a light-emitting device of a second color that are not covered by a second etching protection layer in sequence and removing a second etching protection layer according to an embodiment of the present application;

### REFERENCE NUMERALS

1, array base plate; 2, first electrode; 3, pixel definition layer; 31, pixel opening; 4, light-emitting portion; 5, second electrode; 6, first encapsulation layer; 61, encapsulation unit; 7, isolation structure; 71, first isolation portion; 72, second isolation portion; 73, third isolation portion; 8, gap; 9, isolation opening; 10, light-emitting device; 11, second encapsulation layer; 12, third encapsulation layer; 13, pixel definition material layer; 14, isolation structure material layer; 15, first etching protection layer; 16, second etching protection layer.

### DETAILED DESCRIPTION

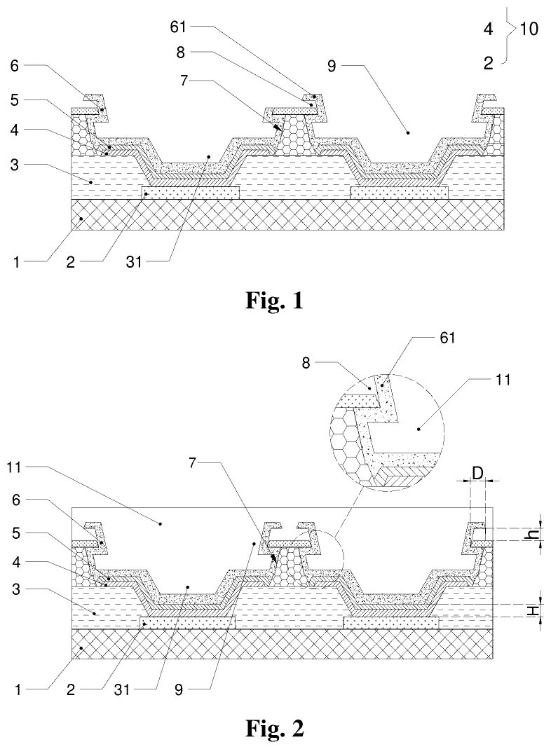

Referring to FIG. 1, a display panel in the related art includes an array base plate 1, an isolation structure 7 located at one side of the array base plate 1, a light-emitting device 10 at least partially located at an isolation opening 9 formed by the isolation structure 7, and a first encapsulation layer 6 located at a side of the isolation structure 7 away from the array base plate 1, in which the first encapsulation layer 6 includes an encapsulation unit 61, and the encapsulation unit 61 extends from a side surface of the isolation structure 7 to a side of the isolation structure 7 away from the array base plate 1.

When manufacturing the display panel in the related art, a vapor-deposition material above the isolation structure 7 is removed in a wet process of an etching process, so that a gap 8 is provided between a part of the encapsulation unit 61 located at the side of the isolation structure 7 away from the array base plate 1 and the side of the isolation structure 7 away from the array base plate 1. Therefore, the encapsulation unit 61 located at the side of the isolation structure 7 away from the array base plate 1 is in an overhanging state, and then the encapsulation unit 61 in the overhanging state is likely to break in a subsequent process, so that the stability of the display panel is relatively poor, which finally affects the display quality of the display panel.

In view of this, the embodiments of the present application provide a solution that can improve the stability of the display panel, and the solution according to the embodiments of the present application is described in detail below.

Referring to FIG. 2, the present embodiment provides a display panel, including an array base plate 1, an isolation structure 7, a light-emitting device 10, a first encapsulation layer 6, and a second encapsulation layer 11.

The array base plate 1 may include a substrate and a plurality of drive units located at a side of the substrate, and each drive unit may include one or more semiconductor switching devices. The semiconductor switching device may be formed by cooperation of a plurality of film layers in the array base plate 1. For example, the semiconductor switching device may be a thin film transistor formed by cooperation of a plurality of film layers.

The isolation structure 7 is located at one side of the array base plate 1, the isolation structure 7 encloses and forms an isolation opening 9, and at least a part of the light-emitting device 10 is located in the isolation opening 9.

The light-emitting device 10 includes a red light-emitting device, a blue light-emitting device, and a green light-emitting device.

The composition, manufacturing, and other contents of the isolation structure 7 are further described in patent applications No. PCT/CN2023/134518, CN 202310759370.2, CN 202310740412.8, CN 202310707209.0, CN 202311346196.5, and CN 202310692671.8 for reference.

The first encapsulation layer 6 is located at a side of the light-emitting device 10 away from the array base plate 1, the first encapsulation layer 6 includes an encapsulation unit 61, the encapsulation unit 61 extends from a side surface of the isolation structure 7 to a side of the isolation structure 7 away from the array base plate 1, the side surface of the isolation structure 7 is a surface of the isolation structure 7 facing the isolation opening 9, and a gap 8 is provided between the encapsulation unit 61 located at the side of the isolation structure 7 away from the array base plate 1 and the side of the isolation structure 7 away from the array base plate 1; and the second encapsulation layer 11 is located at a side of the first encapsulation layer 6 away from the array base plate 1, and at least a part of the second encapsulation layer 11 extends into the gap 8.

In a patterning process of the light-emitting device, the first encapsulation layer 6 forms the encapsulation unit 61, and finally forms a plurality of encapsulation units 61 arranged at intervals. The encapsulation unit 61 may independently encapsulate the light-emitting device 10, so that the display characteristics of the display panel can be improved.

Two adjacent encapsulation units 61 are spaced apart at the side of the isolation structure 7 away from the array base plate 1, an orthographic projection of the encapsulation unit 61 on the array base plate 1 covers an orthographic projection of the isolation opening 9 on the array base plate 1 and an orthographic projection of a part of the isolation structure 7 on the array base plate 1. When the second encapsulation layer 11 is formed, a material of the second encapsulation layer 11 will flow into the gap 8 and fill the gap 8, the second encapsulation layer 11 located in the gap 8 can provide support for the encapsulation unit 61 located at the side of the isolation structure 7 away from the array base plate 1, and in a subsequent process, the encapsulation unit 61 is less likely to break, so that the stability and yield of the display panel can be improved.

Based on the above design, in the present embodiment, the second encapsulation layer 11 can provide support for the overhanging encapsulation unit 61 by extending at least a part of the second encapsulation layer 11 into the gap 8, which can improve the stability of the encapsulation unit 61 located at the side of the isolation structure 7 away from the array base plate 1, so that the encapsulation unit 61 is less likely to break, and thus the stability of the display panel can be improved.

In some possible implementations, with further reference to FIG. 2, the light-emitting device 10 includes a first electrode layer, a light-emitting functional layer, and a second electrode layer that are stacked in sequence along a direction away from the array base plate 1, and the first encapsulation layer 6 is located at a side of the second electrode layer away from the array base plate 1; and the first electrode layer includes a first electrode 2, the light-emitting functional layer includes a light-emitting portion 4, the second electrode layer includes a second electrode 5, an orthographic projection of the isolation opening 9 on the array base plate 1 at least partially overlaps an orthographic projection of the first electrode 2 on the array base plate 1, the light-emitting portion 4 is located in the isolation opening 9, and the second electrode 5 is electrically connected with the isolation structure 7.

The display panel further comprises a pixel definition layer 3 located at a side of the first electrode layer away from the array base plate 1, and the isolation structure 7 is located at one a of the pixel definition layer 3 away from the array base plate 1; the pixel definition layer 3 comprises a pixel opening 31 exposing at least a part of the first electrode 2, and an orthographic projection of the isolation structure 7 on the array base plate 1 is located between orthographic projections of two adjacent pixel openings 31 on the array base plate 1; and an orthographic projection of the pixel opening 31 on the array base plate 1 is located within the orthographic projection of the isolation opening 9 on the array base plate 1.

When the light-emitting functional layer is formed, the light-emitting functional layer is partitioned by the isolation structure 7 to form a plurality of light-emitting portions 4 arranged at intervals. When the second electrode layer is formed, the second electrode layer is partitioned by the isolation structure 7 to form a plurality of second electrodes 5 arranged at intervals. The isolation structure 7 includes an electrically conductive material, the second electrode 5 is electrically connected with the isolation structure 7, and one first electrode 2, one light-emitting portion 4, and one second electrode 5 form one light-emitting device 10. Herein, the first electrode 2 is an anode and the second electrode 5 is a cathode.

In some possible implementations, along a direction perpendicular to the array base plate 1, a height h of the gap is greater than a thickness of the light-emitting functional layer; along the direction perpendicular to the array base plate 1, the height h of the gap is less than a distance from a side of the second electrode 5 away from the array base plate 1 to a side of the first electrode 2 close to the array base plate 1; and heights of gaps corresponding to light-emitting devices 10 of different colors are not equal.

Preferably, with further reference to FIG. 2, along the direction perpendicular to the array base plate 1, the height h of the gap 8 is equal to a distance H from a side of the first electrode 2 of the light-emitting device away from the array base plate 1 to a side of the encapsulation unit 61 close to the array base plate 1.

In the process of manufacturing the display panel, the light-emitting functional layer and the second electrode layer are provided between a part of the encapsulation unit 61 located at the side of the isolation structure 7 away from the array base plate 1 and the side of the isolation structure 7 away from the array base plate 1. After the manufacturing of the display panel is completed, the light-emitting functional layer and the second electrode layer that are located between the part of the encapsulation unit 61 located at the side of the isolation structure 7 away from the array base plate 1 and the side of the isolation structure 7 away from the array base plate 1 are removed. Therefore, along the direction perpendicular to the array base plate 1, the height h of the gap 8 is equal to a sum of thicknesses of the light-emitting functional layer and the second electrode layer for the light-emitting device. In this way, when the second encapsulation layer 11 is formed, the material of the second encapsulation layer 11 fills the gap 8 more easily, so that the stability of the display panel can be further improved.

In some possible implementations, with further reference to FIG. 2, along the direction perpendicular to the array base plate 1, the height h of the gap 8 ranges from 1000 Å to 5000 Å. For example, the height h may be 1000 Å, 1500 Å, 2000 Å, 3000 Å, 4000 Å, 4500 Å, or 5000 Å, etc. The stability of the encapsulation unit 61 can be further improved by reasonably setting the height h.

In some possible implementations, with further reference to FIG. 2, a minimum distance D between an orthographic projection of an edge of the encapsulation unit 61 on the array base plate 1 and an orthographic projection of an edge of the isolation structure 7 on the array base plate 1 is 1 μm to 2 μm. For example, the minimum distance D may be 1 μm, 1.2 μm, 1.5 μm, 1.8 μm, or 2 μm, etc. The minimum distance D is a length of an overhanging portion of the encapsulation unit 61 located at the side of the isolation structure 7 away from the array base plate 1 along a horizontal direction. The second encapsulation layer 11 can fully fill the gap 8 more easily by reasonably optimizing the minimum distance D, so that the stability of the display panel can be further improved.

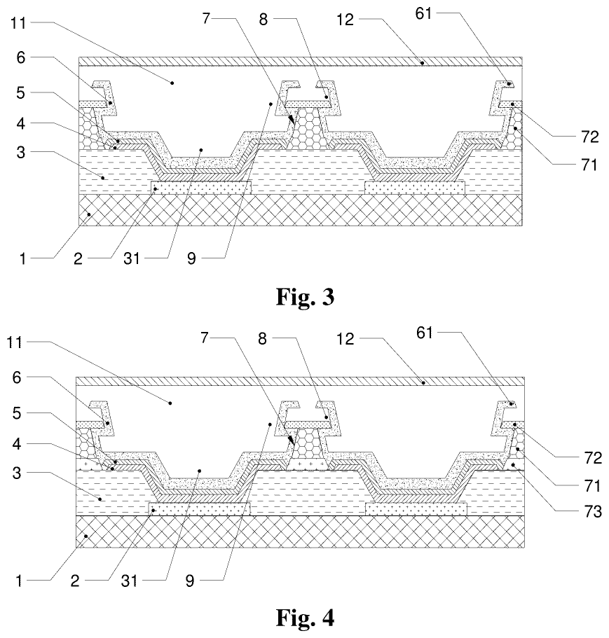

Preferably, referring to FIG. 3, the display panel further includes a third encapsulation layer 12 located at a side of the second encapsulation layer 11 away from the array base plate 1, and the side of the second encapsulation layer 11 away from the array base plate 1 is planarized; and a material of the first encapsulation layer 6 and a material of the third encapsulation layer 12 each includes an inorganic material, and a material of the second encapsulation layer 11 includes an organic material.

The third encapsulation layer 12 can further improve the encapsulation effect on the display panel; and the side of the second encapsulation layer 11 away from the array base plate 1 is planarized, so that the display quality of the display panel can be further improved.

In some possible implementations, with further reference to FIG. 3, the isolation structure 7 includes a first isolation portion 71 and a second isolation portion 72 that are stacked in sequence along a direction away from the array base plate 1, and an orthographic projection of a side of the first isolation portion 71 away from the array base plate on the array base plate 1 is located within an orthographic projection of the second isolation portion 72 on the array base plate 1.

Since the second isolation portion 72 is located at a side of the first isolation portion 71 away from the array base plate 1, and a lateral width of the second isolation portion 72 is greater than a lateral width of the side of the first isolation portion 71 away from the array base plate 1, the second isolation portion 72 may cause the light-emitting functional layer and the second electrode layer to be separated at the isolation structure 7. In this way, the isolation structure 7 formed by the first isolation portion 71 and the second isolation portion 72 can cause each light-emitting device 10 to be encapsulated independently.

In some possible implementations, with further reference to FIG. 3, the second electrode 5 of the light-emitting device 10 is electrically connected with the first isolation portion 71; and/or referring to FIG. 4, the isolation structure 7 further includes a third isolation portion 73 located at a side of the first isolation portion 71 facing the array base plate 1, and the second electrode 5 of the light-emitting device 10 is electrically connected with the third isolation portion 73; a material of the third isolation portion 73 includes molybdenum; and/or a material of the first isolation portion 71 includes aluminium; and/or a material of the second isolation portion 72 includes titanium. In this way, when the isolation structure 7 partitions the second electrode layer into the second electrode 5, the second electrode 5 is electrically connected with the first isolation portion 71 and/or the third isolation portion 73 more easily.

In summary, in the present application, the second encapsulation layer 11 can provide support for the overhanging encapsulation unit 61 by extending at least a part of the second encapsulation layer 11 into the gap 8, which can improve the stability of the encapsulation unit 61 located at the side of the isolation structure 7 away from the array base plate 1, so that the encapsulation unit 61 is less likely to break, and thus the stability of the display panel can be improved.

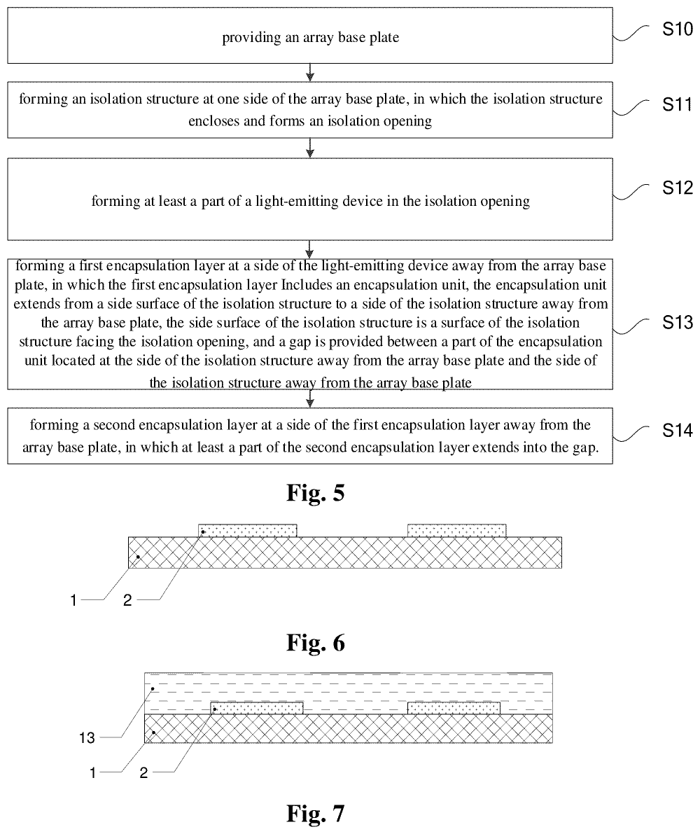

In some possible implementations, referring to FIG. 5, the present application further provides a manufacturing method for a display panel, including S10 to S14.

S10: providing an array base plate 1.

The array base plate 1 may include a substrate and a plurality of drive units located at a side of the substrate, and each drive unit may include one or more semiconductor switching devices. The semiconductor switching device may be formed by cooperation of a plurality of film layers in the array base plate 1. For example, the semiconductor switching device may be a thin film transistor formed by cooperation of a plurality of film layers.

S11: forming an isolation structure 7 at one side of the array base plate 1, in which the isolation structure 7 encloses and forms an isolation opening 9.

Referring to FIG. 6, a first electrode layer is formed at one side of the array base plate 1, the first electrode layer includes a plurality of first electrodes 2 that are arranged at intervals.

Referring to FIG. 7, a pixel definition material layer 13 is formed at a side of the first electrode layer away from the array base plate 1.

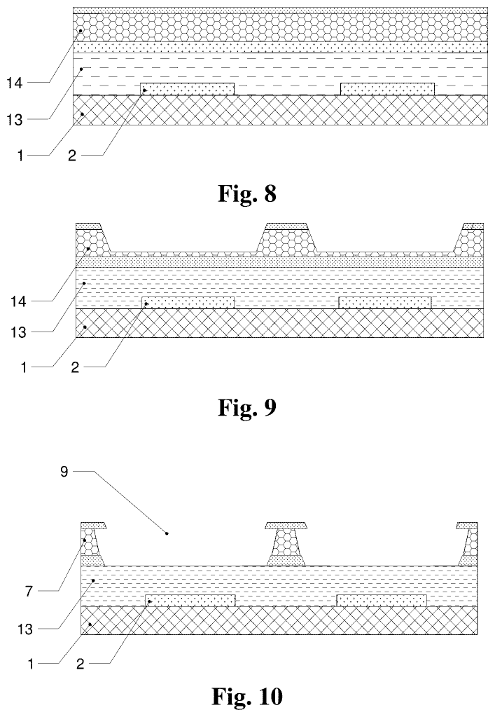

Referring to FIG. 8, an isolation structure material layer 14 is formed at a side of the pixel definition material layer 13 away from the array base plate 1.

Referring to FIG. 9, a dry etching treatment is performed on the insulation structure material layer 14.

Referring to FIG. 10, the isolation structure material layer 14 is patterned to form the isolation structure 7.

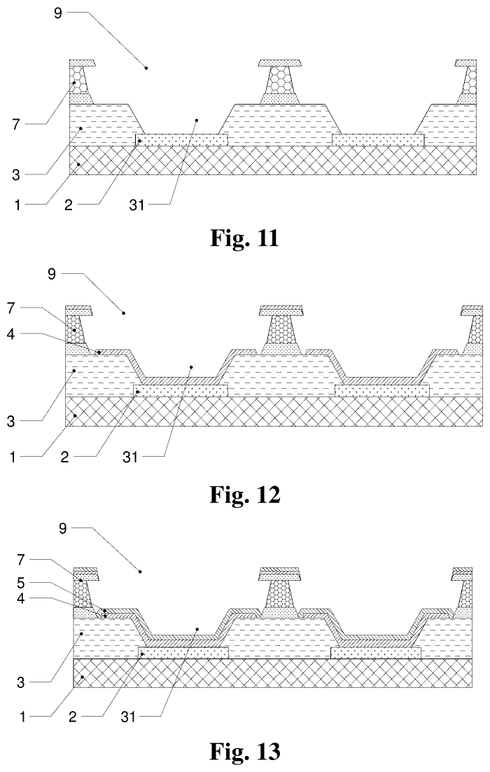

Referring to FIG. 11, the pixel definition material layer 13 is patterned to form a pixel definition layer 3, in which the pixel definition layer 3 includes a pixel opening 31 exposing at least a part of the first electrode 2, and an orthographic projection of the pixel opening 31 on the array base plate 1 is located within an orthographic projection of the isolation opening 9 on the array base plate 1.

S12: forming at least a part of a light-emitting device 10 in the isolation opening 9.

Referring to FIG. 12, a light-emitting functional layer for a light-emitting device of a first color is formed at a side of the isolation structure away 7 from the array base plate 1.

The light-emitting functional layer is separated at the isolation structure 7, so that at least a part of the light-emitting functional layer is located in the isolation opening 9 to form a light-emitting portion 4, and by controlling the vapor-deposition angle, the light-emitting portion 4 may not be in contact with the electrically conductive isolation structure 7.

Referring to FIG. 13, a second electrode layer is formed at a side of the light-emitting functional layer for the light-emitting device of the first color away from the array base plate 1.

The second electrode layer is separated at the isolation structure 7, so that at least a part of the second electrode layer is located in the isolation opening 9 to form a second electrode 5, and by controlling the vapor-deposition angle, the second electrode 5 can extend from the isolation opening 9 to be in electrical contact with the isolation structure 7, so as to connect adjacent second electrodes 5 or connect the second electrode 5 to other circuits. In this way, the difficulty in manufacturing the display panel can be reduced.

S13: forming a first encapsulation layer 6 at a side of the light-emitting device 10 away from the array base plate 1, wherein the first encapsulation layer 6 comprises an encapsulation unit 61, the encapsulation unit 61 extends from a side surface of the isolation structure 7 to a side of the isolation structure 7 away from the array base plate 1, the side surface of the isolation structure 7 is a surface of the isolation structure 7 facing the isolation opening 9, and a gap 8 is provided between the encapsulation unit 61 located at the side of the isolation structure 7 away from the array base plate 1 and the side of the isolation structure 7 away from the array base plate 1.

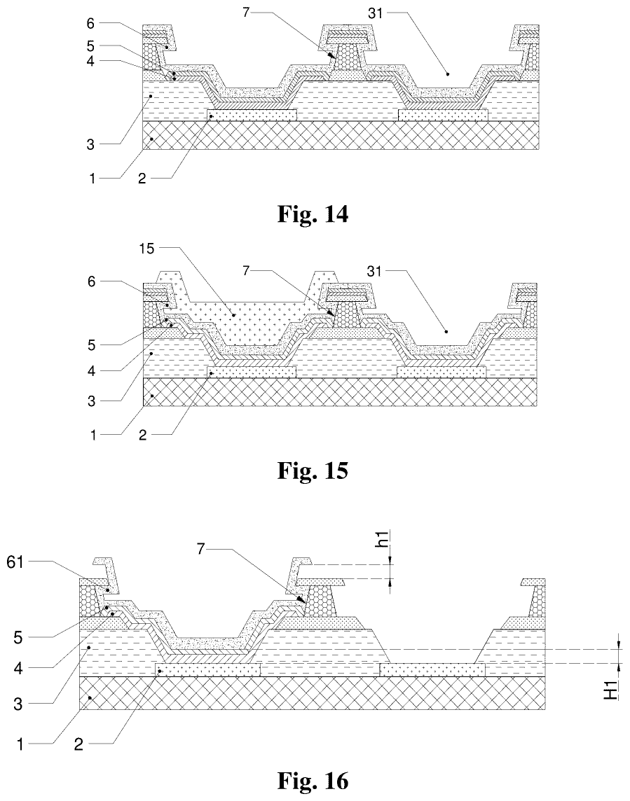

Referring to FIG. 14, the first encapsulation layer 6 is formed at a side of the second electrode layer away from the array base plate 1, and the first encapsulation layer 6 covers both the second electrode layer located at the side of the isolation structure 7 away from the array base plate 1 and the second electrode layer located in the isolation opening 9.

Referring to FIG. 15, a first etching protection layer 15 is formed at an isolation opening 9 corresponding to the light-emitting device of the first color.

The light-emitting device 10 may include the light-emitting device of the first color, a light-emitting device of a second color, and a light-emitting device of a third color, in which the light-emitting device of the first color may be a red light-emitting device, the light-emitting device of the second color may be a green light-emitting device, and the light-emitting device of the third color may be a blue light-emitting device. In some embodiments, the first etching protection layer 15 covers at least a portion of the isolation structure 7 on one side away from the array base plate 1. The first etching protection layer 15 may protect the light-emitting functional layer, the second electrode layer, and the first encapsulation layer 6 that correspond to the light-emitting device of the first color.

Referring to FIG. 16, the first encapsulation layer 6, the light-emitting functional layer, and the second electrode layer that are not covered by the first etching protection layer 15 is removed, and the first etching protection layer 15 is removed, so as to form a light-emitting portion 4, a second electrode 5, and the encapsulation unit 61 in a pixel opening 31 corresponding to the light-emitting device of the first color; in which along a direction perpendicular to the array base plate 1, a height h1 of a gap 8 corresponding to the light-emitting device of the first color is equal to a distance H1 from a side of the first electrode 2 corresponding to the light-emitting device of the first color away from the array base plate 1 to a side of the encapsulation unit 61 close to the array base plate 1.

When the first encapsulation layer 6, the light-emitting functional layer, and the second electrode layer that are not covered by the first etching protection layer 15 are removed, the light-emitting functional layer and the second electrode layer between the encapsulation unit 61 located at the side of the isolation structure 7 away from the array base plate 1 and the isolation structure 7 are removed together. Therefore, along the direction perpendicular to the array base plate 1, the height h1 of the gap 8 corresponding to the light-emitting device of the first color is equal to a sum of thicknesses of the light-emitting portion 4 and the second electrode 5 that correspond to the light-emitting device of the first color. In this way, the light-emitting functional layer and the second electrode layer are completely covered by the encapsulation unit 61, and the light-emitting functional layer and the second electrode layer between the part of the encapsulation unit 61 located at the side of the isolation structure 7 away from the array base plate 1 and the side of the isolation structure 7 away from the array base plate 1 are removed, so that the risks of device contamination and film layer breakage caused by the vapor-deposition material entering the vapor-deposition device after being exposed to air can be reduced.

In this way, the light-emitting portion 4, the second electrode 5, and the encapsulation unit 61 can be formed only in the pixel opening 31 corresponding to the light-emitting device of the first color without a fine mask, and the second electrode 5 can be electrically connected with the isolation structure 7, so that the light-emitting device of the first color can be formed in the pixel opening 31 corresponding to the light-emitting device of the first color at a lower cost.

Referring to FIG. 17, a light-emitting functional layer for a light-emitting device of a second color is formed at the side of the isolation structure 7 away from the array base plate 1, in which the light-emitting functional layer for the light-emitting device of the second color covers a side of the encapsulation unit 61 corresponding to the light-emitting device of the first color away from the base plate 1.

On the basis of forming the light-emitting device of the first color, the light-emitting functional layer for the light-emitting device of the second color is formed subsequently, and the light-emitting functional layer for the light-emitting device of the second color covers the encapsulation unit 61 corresponding to the light-emitting device of the first color, while a light-emitting portion 4 of the light-emitting device of the second color is formed in a pixel opening 31 corresponding to the light-emitting device of the second color.

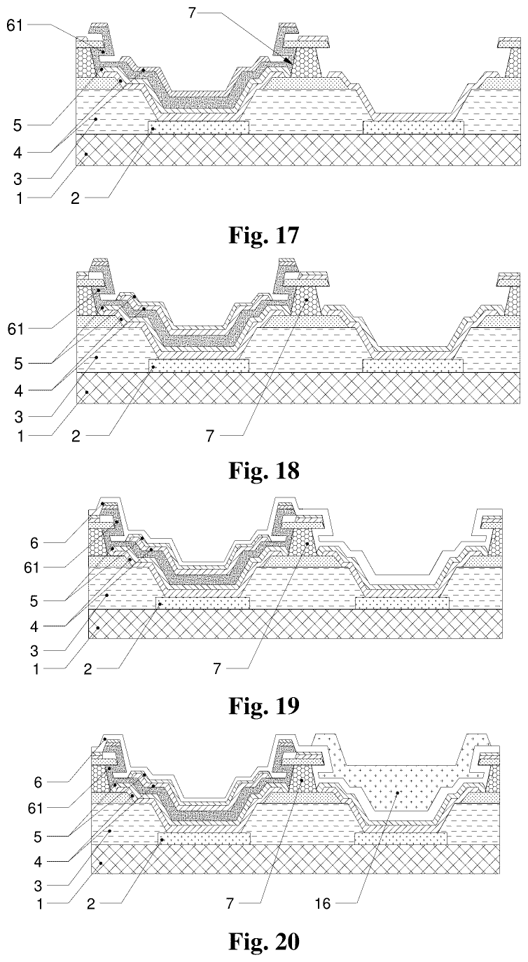

Referring to FIG. 18, a second electrode layer is formed at a side of the light-emitting functional layer for the light-emitting device of the second color away from the array base plate, while a second electrode 5 of the light-emitting device of the second color is formed in the pixel opening 31 corresponding to the light-emitting device of the second color, and the second electrode 5 of the light-emitting device of the second color is electrically connected with the isolation structure 7.

Referring to FIG. 19, the first encapsulation layer 6 is formed at a side of the second electrode layer away from the array base plate 1.

Referring to FIG. 20, a second etching protection layer 16 is formed at an isolation opening corresponding to the light-emitting device of the second color. In some embodiments, the second etching protection layer 16 covers at least a portion of the isolation structure 7 on one side away from the array base plate 1. The second etching protection layer 16 may protect the light-emitting functional layer, the second electrode layer, and the first encapsulation layer 6 that correspond to the light-emitting device of the second color.

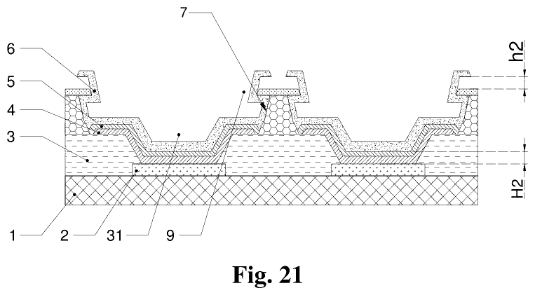

Referring to FIG. 21, the first encapsulation layer 6, the light-emitting functional layer, and the second electrode layer for the light-emitting device of the second color that are not covered by the second etching protection layer 16 are removed, and the second etching protection layer 16 is removed, so as to form a light-emitting portion 4, a second electrode 5, and the encapsulation unit 61 in a pixel opening 31 corresponding to the light-emitting device of the second color; in which along the direction perpendicular to the array base plate 1, a height h2 of a gap 8 corresponding to the light-emitting device of the second color is equal to a distance from a side of the first electrode 2 corresponding to the light-emitting device of the second color away from the array base plate 1 to a side of the encapsulation unit 61 close to the array base plate 1.

When the first encapsulation layer 6, the light-emitting functional layer, and the second electrode layer that are not covered by the second etching protection layer 16 are removed, the light-emitting functional layer and the second electrode layer between the part of the encapsulation unit 61 located at the side of the isolation structure 7 away from the array base plate 1 and the isolation structure 7 are removed together. Therefore, along the direction perpendicular to the array base plate 1, the height h2 of the gap 8 corresponding to the light-emitting device of the second color is equal to a sum of thicknesses of the light-emitting portion 4 and the second electrode 5 that correspond to the light-emitting device of the second color.

In this way, the light-emitting portion 4, the second electrode 5, and the encapsulation unit 61 can be formed only in the pixel opening 31 corresponding to the light-emitting device of the second color without a fine mask, and the second electrode 5 can be electrically connected with the isolation structure 7. In this way, the light-emitting device of the second color can be formed in the pixel opening 31 corresponding to the light-emitting device of the second color at a lower cost.

Similarly, a light-emitting portion 4, a second electrode 5, and an encapsulation unit 61 can be formed in a pixel opening 31 corresponding to a light-emitting device 10 of a third color or more other colors by using the above steps. A plurality of light-emitting devices 10 formed by the above steps are encapsulated independently, so that the light-emitting devices 10 are independent from each other, and thus the optical performance of the display panel can be optimized.

S14: forming a second encapsulation layer 11 at a side of the first encapsulation layer 6 away from the array base plate 1, in which at least a part of the second encapsulation layer 11 extends into the gap 8.

With further reference to FIG. 2, after light-emitting devices 10 of various colors are formed by the above method, the second encapsulation layer 11 is formed at the side of the first encapsulation layer 6 away from the array base plate 1. A material of the second encapsulation layer 11 will flow into the gap 8 and fill the gap 8, the second encapsulation layer 11 located in the gap 8 can provide support for the encapsulation unit 61 located at the side of the isolation structure 7 away from the array base plate 1, and in a subsequent process, the encapsulation unit 61 is less likely to break, so that the stability and yield of the display panel can be improved.

In some possible implementations, the present application further provides an electronic device, including the display panel in the present application, or including the display panel manufactured by the manufacturing method for the display panel in the present application. The electronic device may include a device capable of processing images, such as a server, a personal computer, a notebook computer, and the like. Since the electronic device includes the display panel in the present application, the electronic device has better stability and higher yield.

The technical features of the above embodiments can be combined in any way, and in order to make the description clear, not all the possible combinations of the technical features in the above embodiments are described. However, as long as there is no contradiction among the combinations of these technical features, they should be considered as the scope that the specification recites.

The embodiments described above represent only a few implementations of the present invention and description thereof is relatively specific and detailed, but are not to be construed as limiting the patent scope of the present invention. It should be noted that a person skilled in the art could also make several changes and modifications without departing from the concept of the present invention, which falls within the scope of protection of this invention. Therefore, the protection scope of the present invention should be subject to the appended claims.

What is claimed is:

1. A display panel, comprising:
an array base plate;
an isolation structure located at one side of the array base plate, wherein the isolation structure encloses and forms an isolation opening;
a light-emitting device at least partially located in the isolation opening;
a first encapsulation layer located at a side of the light-emitting device away from the array base plate, wherein the first encapsulation layer comprises an encapsulation unit, the encapsulation unit extends from a side surface of the isolation structure to a side of the isolation structure away from the array base plate, the side surface of the isolation structure is a surface of the isolation structure facing the isolation opening, and a gap is provided between the encapsulation unit located at the side of the isolation structure away from the array base plate and the side of the isolation structure away from the array base plate; and
a second encapsulation layer located at a side of the first encapsulation layer away from the array base plate, wherein at least a part of the second encapsulation layer extends into the gap.

2. The display panel according to claim 1, wherein the light-emitting device comprises a first electrode layer, a light-emitting functional layer, and a second electrode layer which are stacked in sequence along a direction away from the array base plate, and the first encapsulation layer is located at a side of the second electrode layer away from the array base plate.

3. The display panel according to claim 2, wherein the first electrode layer comprises a first electrode, the light-emitting functional layer comprises a light-emitting portion, the second electrode layer comprises a second electrode, an orthographic projection of the isolation opening on the array base plate at least partially overlaps an orthographic projection of the first electrode on the array base plate, the light-emitting portion is located in the isolation opening, and the second electrode is electrically connected with the isolation structure.

4. The display panel according to claim 3, wherein along a direction perpendicular to the array base plate, a height of the gap is greater than a thickness of the light-emitting functional layer;
along the direction perpendicular to the array base plate, the height of the gap is less than a distance from a side of the second electrode away from the array base plate to a side of the first electrode close to the array base plate;
heights of gaps corresponding to light-emitting devices of different colors are not equal;
along the direction perpendicular to the array base plate, the height of the gap is equal to a distance from a side of the first electrode of the light-emitting device away from the array base plate to a side of the first encapsulation layer close to the array base plate; and
along the direction perpendicular to the array base plate, the height of the gap ranges from 1000 Å to 5000 Å.

5. The display panel according to claim 1, wherein a minimum distance between an orthographic projection of an edge of the encapsulation unit on the array base plate and an orthographic projection of an edge of the isolation structure on the array base plate is 1 μm to 2 μm;
two adjacent encapsulation units are spaced apart at the side of the isolation structure away from the array base plate; and
an orthographic projection of the encapsulation unit on the array base plate covers an orthographic projection of the isolation opening on the array base plate and an orthographic projection of a part of the isolation structure on the array base plate.

6. The display panel according to claim 1, wherein the second encapsulation layer fully fills the gap;
a side of the second encapsulation layer away from the array base plate is planarized;
the display panel further comprises a third encapsulation layer located at the side of the second encapsulation layer away from the array base plate;
a material of the first encapsulation layer and a material of the third encapsulation layer each comprises an inorganic material; and
a material of the second encapsulation layer comprises an organic material.

7. The display panel according to claim 2, wherein the display panel further comprises a pixel definition layer located at a side of the first electrode layer away from the array base plate, and the isolation structure is located at a side of the pixel definition layer away from the array base plate; the pixel definition layer comprises a pixel opening exposing at least a part of the first electrode, and an orthographic projection of the isolation structure on the array base plate is located between orthographic projections of two adjacent pixel openings on the array base plate; and
an orthographic projection of the pixel opening on the array base plate is located within the orthographic projection of the isolation opening on the array base plate.

8. The display panel according to claim 1, wherein the isolation structure comprises a first isolation portion and a second isolation portion which are stacked in sequence along a direction away from the array base plate, and an orthographic projection of a side of the first isolation portion away from the array base plate on the array base plate is located within an orthographic projection of the second isolation portion on the array base plate.

9. The display panel according to claim 8, wherein a second electrode of the light-emitting device is electrically connected with the first isolation portion; and/or the isolation structure further comprises a third isolation portion located at a side of the first isolation portion facing the array base plate, and the second electrode of the light-emitting device is electrically connected with the third isolation portion; and
a material of the third isolation portion comprises molybdenum; or a material of the first isolation portion comprises aluminium; or a material of the second isolation portion comprises titanium.

10. A display panel, comprising:
an array base plate;
an isolation structure located at one side of the array base plate, wherein the isolation structure encloses and forms an isolation opening;
a light-emitting device at least partially located in the isolation opening; and
a first encapsulation layer located at a side of the light-emitting device away from the array base plate, wherein the first encapsulation layer comprises an encapsulation unit, the encapsulation unit extends from a side surface of the isolation structure to a side of the isolation structure away from the array base plate, the side surface of the isolation structure is a surface of the isolation structure facing the isolation opening, a gap is provided between the encapsulation unit located at the side of the isolation structure away from the array base plate and the side of the isolation structure away from the array base plate, and heights of gaps corresponding to light-emitting devices of different colors are not equal.

11. The display panel according to claim 10, wherein the light-emitting device comprises a first electrode layer, a light-emitting functional layer, and a second electrode layer which are stacked in sequence along a direction away from the array base plate, and the first encapsulation layer is located at a side of the second electrode layer away from the array base plate.

12. The display panel according to claim 11, wherein the first electrode layer comprises a first electrode, the light-emitting functional layer comprises a light-emitting portion, the second electrode layer comprises a second electrode, an orthographic projection of the isolation opening on the array base plate at least partially overlaps an orthographic projection of the first electrode on the array base plate, the light-emitting portion is located in the isolation opening, and the second electrode is electrically connected with the isolation structure.

13. The display panel according to claim 11, wherein along a direction perpendicular to the array base plate, a height of the gap is greater than a thickness of the light-emitting functional layer corresponding to the gap.

14. The display panel according to claim 12, wherein along a direction perpendicular to the array base plate, a height of the gap is less than a distance from a side of the second electrode corresponding to the gap away from the array base plate to a side of the first electrode corresponding to the gap close to the array base plate.

15. The display panel according to claim 12, wherein along a direction perpendicular to the array base plate, a height of the gap is equal to a distance from a side of the first electrode of the light-emitting device corresponding to the gap away from the array base plate to a side of the first encapsulation layer corresponding to the gap close to the array base plate; and
along the direction perpendicular to the array base plate, the height of the gap ranges from 1000 Å to 5000 Å.

16. A manufacturing method for a display panel, comprising:
providing an array base plate;
forming an isolation structure at one side of the array base plate, wherein the isolation structure encloses and forms an isolation opening;
forming at least a part of a light-emitting device in the isolation opening;
forming a first encapsulation layer at a side of the light-emitting device away from the array base plate, wherein the first encapsulation layer comprises an encapsulation unit, the encapsulation unit extends from a side surface of the isolation structure to a side of the isolation structure away from the array base plate, the side surface of the isolation structure is a surface of the isolation structure facing the isolation opening, and a gap is provided between the encapsulation unit located at the side of the isolation structure away from the array base plate and the side of the isolation structure away from the array base plate; and
forming a second encapsulation layer at a side of the first encapsulation layer away from the array base plate, wherein at least a part of the second encapsulation layer extends into the gap.

17. The manufacturing method for the display panel according to claim 16, wherein the forming the isolation structure at one side of the array base plate comprises:
forming a first electrode layer on one side of the array base plate, wherein the first electrode layer comprises a plurality of first electrodes arranged at intervals;
forming a pixel definition material layer at a side of the first electrode layer away from the array base plate;
forming an isolation structure material layer at a side of the pixel definition material layer away from the array base plate;
patterning the isolation structure material layer to form the isolation structure; and
patterning the pixel definition material layer to form a pixel definition layer, wherein the pixel definition layer comprises a pixel opening exposing at least a part of the first electrode, and an orthographic projection of the pixel opening on the array base plate is located within an orthographic projection of the isolation opening on the array base plate.

18. The manufacturing method for the display panel according to claim 17, wherein the forming at least a part of the light-emitting device in the isolation opening comprises:
forming a light-emitting functional layer for a light-emitting device of a first color at a side of the isolation structure away from the array base plate; and
forming a second electrode layer at a side of the light-emitting functional layer for the light-emitting device of the first color away from the array base plate.

19. The manufacturing method for the display panel according to claim 18, wherein the forming the first encapsulation layer at the side of the light-emitting device away from the array base plate comprises:
forming the first encapsulation layer at a side of the second electrode layer away from the array base plate;
forming a first etching protection layer at an isolation opening corresponding to the light-emitting device of the first color; and
removing the first encapsulation layer, the light-emitting functional layer, and the second electrode layer which are not covered by the first etching protection layer, and removing the first etching protection layer, so as to form a light-emitting portion, a second electrode, and the encapsulation unit in a pixel opening corresponding to the light-emitting device of the first color; wherein along a direction perpendicular to the array base plate, a height of a gap corresponding to the light-emitting device of the first color is equal to a distance from a side of the first electrode corresponding to the light-emitting device of the first color away from the array base plate to a side of the encapsulation unit close to the array base plate.

20. The manufacturing method for the display panel according to claim 19, wherein after the removing the first encapsulation layer, the light-emitting functional layer, and the second electrode layer which are not covered by the first etching protection layer, and removing the first etching protection layer, the manufacturing method further comprises:
forming a light-emitting functional layer for a light-emitting device of a second color at the side of the isolation structure away from the array base plate, wherein the light-emitting functional layer for the light-emitting device of the second color covers a side of the encapsulation unit corresponding to the light-emitting device of the first color away from the base plate;
forming a second electrode layer at a side of the light-emitting functional layer for the light-emitting device of the second color away from the array base plate;
forming the first encapsulation layer at a side of the second electrode layer away from the array base plate;
forming a second etching protection layer at an isolation opening corresponding to the light-emitting device of the second color; and
removing the first encapsulation layer, the light-emitting functional layer, and the second electrode layer for the light-emitting device of the second color which are not covered by the second etching protection layer, and removing the second etching protection layer, so as to form a light-emitting portion, a second electrode, and the encapsulation unit in a pixel opening corresponding to the light-emitting device of the second color; wherein along the direction perpendicular to the array base plate, a height of a gap corresponding to the light-emitting device of the second color is equal to a distance from a side of the first electrode corresponding to the light-emitting device of the second color away from the array base plate to a side of the encapsulation unit close to the array base plate.
